(19) United States
(12) Patent Application Publication
(10) Pub. No.: US 2025/0074217 A1
(43) Pub. Date: Mar. 6, 2025

(54) LOW-VOLTAGE BATTERY UNIT, VERIFICATION METHOD FOR THE SAME, AND POWER SYSTEM HAVING THE SAME FOR FCEV TYPE COMMERCIAL SPECIAL-PURPOSE VEHICLE

(71) Applicants: Hyundai Motor Company, Seoul (KR); Kia Corporation, Seoul (KR); Hyundai AutoEver Corp., Seoul (KR)

(72) Inventors: Jae Yong Lee, Chungju (KR); Seung Deuk Bae, Jeonju (KR); Yun Jae Jo, Seoul (KR); Ki Hyun Kwon, Hwaseong (KR)

(21) Appl. No.: 18/810,263

(22) Filed: Aug. 20, 2024

(30) Foreign Application Priority Data
Aug. 29, 2023 (KR) 10-2023-0113577

(51) Int. Cl. B60L 50/71; B60R 16/033; B60R 16/04; H02J 7/00

(52) U.S. Cl. CPC B60L 50/71; B60R 16/033; B60R 16/04; H02J 7/0014; B60L 2210/12

(57) ABSTRACT

The present disclosure provides a low-voltage battery unit of a fuel cell electric vehicle (FCEV) type commercial special purpose vehicle. The low-voltage battery unit features a dualized structure by using a 12V LDC and adopting a battery exclusively providing DC12V, instead of using a low-voltage DC-DC converter (LDC) for 24V and a battery equalizer (BEQ) to supply 24V and 12V in the low-voltage battery unit.

### CROSS-REFERENCE TO RELATED APPLICATION

The present application claims under 35 U.S.C. § 119(a) the benefit of Korean Patent Application No. 10-2023-0113577, filed on Aug. 29, 2023, the entire contents of which is incorporated herein by reference in its entirety.

### Background

### Technical Field

The present disclosure relates to a low-voltage battery unit, design verification method for the same, and power system having the same for such as a commercial fuel cell electric vehicle (FCEV) type commercial special-purpose vehicle.

### Background

In general, an electric vehicle (EV) or a fuel cell vehicle (FCEV), both of which are eco-friendly vehicles, includes a low-voltage battery (also referred to as an “auxiliary battery”) to supply power to electric loads operating at a low voltage.

In the case of FCEV type commercial special purpose vehicles (truck, fire truck, tank truck, vehicle carrying vehicle, freezing tower vehicle, snow removal vehicle, etc.), one battery for 24V or two batteries for 12V are connected in series to supply the required power of electric loads for 24V. Recently, a structural change of the low-voltage battery has become necessary to supply 12V, as the use demand for electric loads requiring 12V power has increased.

To this end, as shown in FIG. 1, two 12V battery reeds B1 and B2 may be connected in series to supply 24V power to an electric load for 24V and to supply a branch voltage to the electric load for 12V using the battery equalizer (BEQ) 11, but a deviation in charge and discharge flow between the first battery B1 and the second battery B2 may occur due to a difference in power consumption, and the first battery B1 may be completely discharged often due to accumulation of such a situation.

In other words, the first battery B1 is used for both the 12V power supply and the 24V power supply while the second battery B2 is used only for the 24V power supply. This difference in power consumption leads to an increase in the charge and discharge flow increases.

Therefore, since the starting power of the FCEV special purpose vehicles is 24V, when the first battery B1 is completely discharged, there is a problem that the engine cannot be started by only the second battery B2.

In addition, the battery life cycle is generally about 3 to 5 years, but once discharged, the residual life is shortened to 70%, and when secondary discharge occurs, the residual life is rapidly reduced to 30%.

Therefore, when the first battery B1 is completely discharged two to three times or more, the first battery B1 should be replaced. The first battery B1 and the second battery B2 are integrated in an exterior structure. When replacing the first battery B1, a cost burden of replacing the entire first battery B1 with the entire second battery B2 may be increased.

Therefore, it is necessary to change the structure of the low-voltage battery unit to suppress the deviation caused by the imbalance in power consumption. This change aims to maintain a stable supply of DC power at 12V and 24V and to reduce unnecessary cost burdens on consumers.

However, even though it is theoretically possible, it is unknown whether an expected effect will be generated in the actual application, and since an unexpected adverse effect may be generated, it is not easy to change the structure.

Therefore, there is a need for a design change of the low-voltage battery unit and a design verification method according thereto.

### SUMMARY

One embodiment of the present disclosure aims to solve the above-described problem.

An object of the present disclosure is to provide a low-voltage battery unit of a fuel cell electric vehicle (FCEV) type commercial special purpose vehicle, which is dualized in structure by using a z/12V LDC and adopting a battery exclusively providing DC12V instead of using a low-voltage DC-DC converter (LDC) for 24V and a battery equalizer (BEQ) to supply 24V and 12V in the low-voltage battery unit.

Another object of the present disclosure is to provide a verification method for checking whether such a change of a low-voltage battery unit is effective, and a power system having the changed low-voltage battery unit.

To achieve the objects of the present disclosure, as embodied and broadly described herein, there is provided a low-voltage battery unit for a commercial electric vehicle comprising a first low-voltage DC-DC converter (LDC) converting a high-voltage power into a first low-voltage and outputting the first low-voltage, a first low-voltage battery charged by a power output from the first LDC and supplying a power of the first low-voltage to a first electric load, a second LDC converting the high-voltage power into a second low-voltage and outputting the second low-voltage, and a second low-voltage battery charged by a power output from the second LDC and supplying a power of the second low-voltage to a second electric load.

In at least one embodiment of the present disclosure, the high-voltage power is supplied from a hydrogen fuel cell.

In at least one embodiment of the present disclosure, the first low-voltage battery includes two 12V-105 Ah absorbed glass mat (AGM) batteries connected in series.

In at least one embodiment of the present disclosure, the second low-voltage battery includes one 12V-50 Ah AGM battery.

In at least one embodiment of the present disclosure, the first LDC includes 24V LDC.

In at least one embodiment of the present disclosure, the second LDC includes 12V LDC.

In accordance with an embodiment of the present disclosure to achieve the object, there is provided a design verification method for a low-voltage battery unit for a commercial electric vehicle, which is used to verify a change in a structure of a low-voltage configuration unit that supplies DC24V and DC12V to an electric load side in the commercial electric vehicle. The method includes collecting vehicle actual data comprising a consumption measurement amount of each electric load of the vehicle, a configuration of a dual power low-voltage circuit, a battery specification, a LDC/BEQ (battery equalizer) electrical specification, control logic, wire resistance information, and vehicle information, modeling respective topology circuits of a first topology of a current structure, a second topology of an improvement structure to be verified, and a third topology obtained by modifying the second topology, based on the vehicle actual data, constructing electric models of components applicable to each of the modeled topology circuits, the specification of the electric loads, and an operating environment of the vehicle, in a simulation environment, and verifying by simulation, obtaining results of electric characteristics through a change of a verification condition in the simulation environment, and comparing the results for the first topology to the third topology to verify an optimized structure and corresponding components of the structure.

The step of verifying by simulation may comprise electing a verification topology model circuit from the stored topology models; applying electric load specifications to the selected verification topology model circuit; applying specifications for each component in the model circuit of the selected verification topology model circuit; or applying vehicle state and driving time conditions to the selected verification topology model circuit.

The method may comprise executing condition application verification mode by assessing vehicle voltage safety, charging and discharging of a battery, component specification suitability, or consumption amount of power to ensure that requirements of each field are satisfied.

To achieve these and other advantages and in accordance with the purpose of the present disclosure, as embodied and broadly described herein, there is provided a power system of a commercial electric vehicle comprising an inverter for driving a motor, a high-voltage power source for outputting a high-voltage power as a power source for operating the motor, a main relay for opening or closing a power connection path between the high-voltage power source and the inverter according to a control signal, a management system (MS) for controlling on/off of the main relay by generating the control signal, a first low-voltage DC-DC converter (LDC) for converting the high-voltage power into a first low-voltage and outputting the first low-voltage, a first low-voltage battery charged by a power output from the first LDC and supplying a power of the first low-voltage to a first electric load, a second LDC for converting the high-voltage power into a second low-voltage and outputting the second low-voltage, and a second low-voltage battery charged by the power output from the 2LDC and supplying a power of the second low-voltage to a second electric load.

In at least one embodied power system of the present disclosure, the power system further comprises a control unit configured to control operation states of the MS, the first LDC, and the second LDC.

In at least one embodied power system of the present disclosure, the high-voltage power source includes a hydrogen fuel cell.

In at least one embodied power system of the present disclosure, the first low-voltage battery includes two 12V-105 Ah AGM batteries connected in series.

In at least one embodied power system of the present disclosure, the second low-voltage battery includes one 12V-50 Ah AGM battery.

In at least one embodied power system of the present disclosure, the first LDC includes 24V LDC.

In at least one embodied power system of the present disclosure, the second LDC includes 12V LDC.

According to one embodiment of the present disclosure, a low-voltage battery unit, design verification method for the same, and power system having the same according to a dualized design, and a power system to which the same is applied are provided such that structure changes such as an optimal structure change are possible. The stability of components is thus obtained and the burden of cost increase is also minimized. Such structure changes can be made through topology verification simulation with respect to a commercial vehicle of which it is difficult to change the structure in an improved manner. The problem of reliability degradation of small products can be solved also by dualizing low-voltage supply of DC 24V and an DC 12V such that DC 24V and an DC 12V are operated independently, respectively.

### BRIEF DESCRIPTION OF DRAWING

FIG. 1 is a schematic example of a low-voltage battery unit of an FCEV type commercial special purpose vehicle.

FIG. 2 is a block diagram of a low-voltage battery unit of an FCEV type commercial special purpose vehicle according to an embodiment of the present disclosure.

FIG. 3 is a flow diagram illustrating a design verification process for a low-voltage battery unit of an FCEV type commercial special purpose vehicle according to an embodiment of the present disclosure.

FIG. 4 is a circuit model schematic diagram for a simulation for verifying a design change of a low-voltage battery unit of an FCEV type commercial special purpose vehicle according to an embodiment of the present disclosure.

FIG. 5 is a schematic diagram of a simulation circuit model for comparison and verification of design changes of a low-voltage battery unit of an FCEV type commercial special purpose vehicle according to an embodiment of the present disclosure.

FIG. 6 is a result table in which the performance of each circuit model is comparatively verified.

FIG. 7 is an exemplary block diagram of a power system configuration of an FCEV type commercial special purpose vehicle to which a low-voltage battery unit according to an exemplary embodiment of the present disclosure is applied.

### DETAILED DESCRIPTIONS

Since the present disclosure is modified in various ways and has various embodiments, specific embodiments will be illustrated and described in the drawings. However, this is not intended to limit the present disclosure to specific embodiments, and it should be understood that the present disclosure includes all modifications, equivalents, and replacements included on the idea and technical scope of the present disclosure.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The suffixes “module” and “unit” used herein are used only for name distinction between elements and should not be construed as being physiochemically divided or separated or assumed that they can be divided or separated.

Terms including ordinals such as “first,” “second,” and the like may be used to describe various elements, but the elements are not limited by the terms. The terms are used only for the purpose of distinguishing one element from another element.

The term “and/or” is used to include any combination of a plurality of items to be included. For example, “A and/or B” includes all three cases such as “A”, “B”, and “A and B”.

When an element is “connected” or “linked” to another element, it should be understood that the element may be directly connected or connected to another element, but another element may exist in between.

The terminology used herein is for the purpose of describing particular embodiments only and is not intended to be limiting of the disclosure. Singular expressions include plural expressions, unless the context clearly indicates otherwise. In the present application, it should be understood that the term “include” or “have” indicates that a feature, a number, a step, an operation, a component, a part, or a combination thereof described in the specification is present, but does not exclude the possibility of existence or addition of one or more other features, numbers, steps, operations, components, parts, or combinations thereof in advance.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about”.

Unless otherwise defined, all terms used herein, including technical or scientific terms, have the same meaning as that generally understood by those skilled in the art. It will be understood that terms, such as those defined in commonly used dictionaries, should be interpreted as having a meaning that is consistent with their meaning in the context of the relevant art and will not be interpreted in an idealized or overly formal sense unless expressly so defined herein.

In addition, the term “unit” or “control unit” is a term widely used for naming a controller that commands a specific function, and does not mean a generic function unit. For example, each unit or control unit may include a communication device communicating with another controller or sensor, a computer-readable recording medium storing an operating system or a logic command, input/output information, and the like, in order to control a function in charge, and one or more processors performing determination, calculation, determination, and the like necessary for controlling a function in charge.

Meanwhile, the processor includes a semiconductor integrated circuit and/or electronic devices that perform at least one or more of comparison, determination, calculation, and determination in order to achieve a programmed function. For example, the processor may be a computer, a microprocessor, a CPU, an ASIC, and a circuitry (logic circuits), or a combination thereof.

In addition, the computer-readable recording medium (or simply referred to as a memory) includes all types of storage devices in which data that can be read by a computer system is stored. For example, the memory may include at least one type of a flash memory of a hard disk, of a microchip, of a card (e.g., a secure digital (SD) card or an eXtream digital (XD) card), etc., and at least a memory type of a Random Access Memory (RAM), of a Static RAM (SRAM), of a Read-Only Memory (ROM), of a Programmable ROM (PROM), of an Electrically Erasable PROM (EEPROM), of a Magnetic RAM (MRAM), of a magnetic disk, and of an optical disk.

The recording medium is electrically connected to the processor, and the processor retrieves and records data from the recording medium. The recording medium and the processor either may be integrated or may be physically separated.

Hereinafter, a low-voltage battery unit, design verification method for the same according to a dualized design change for supplying 24V and 12V of FCEV type commercial special purpose vehicles according to the present disclosure will be described with reference to the accompanying drawings.

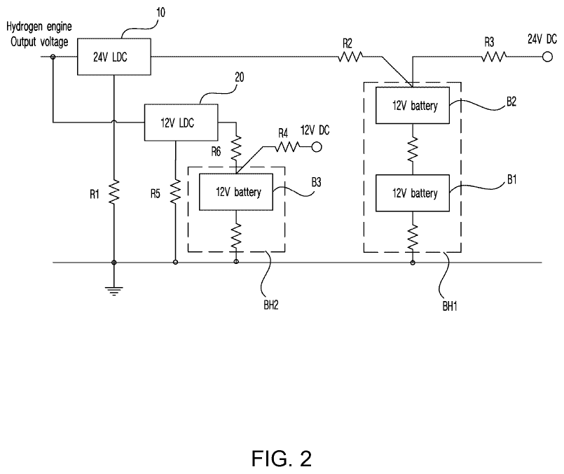

As shown in FIG. 2, the low-voltage battery unit of an FCEV type commercial special purpose vehicle according to the present disclosure includes a 24V LDC 10, which is a first LDC for converting a high-voltage power generated from a hydrogen fuel cell into 24V DC and outputting the DC power, a battery pack BH1, which is charged by the power output from the 24V LDC 10 and supplies the power to an electric load (not shown) for 24V located on a discharge path, a 12V LDC 20, which is a second LDC for converting a high-voltage power generated from the hydrogen fuel cell into 12V DC and outputting the DC power, and a battery pack BH2, which is charged by the power output from the 12V LDC 20 and supplies the power to a battery pack for 12V (not shown) located on the discharge path.

The resistors R1 and R5 are resistors for stabilizing the ground potential of the LDC 10 and 20, the resistors R2 and R6 are resistors for stabilizing the output power of the LDC 10 and 20, and the resistors R3 and R4 are resistors for stabilizing the output power of the battery pack BH1 and BH2.

In addition, the resistors without reference numerals are internal resistors of the battery or resistors for stabilization, and their description will be omitted.

The wiring of the circuit illustrated in FIG. 2 is an example and is not limited thereto.

The expected effect of the low-voltage battery unit implemented as described above should be verified, and a model-based design simulation is used as a simulation method for such verification.

In general, the model-based design simulation includes Software in the Loop Simulation (SILS), Model in the Loop Simulation (MILS), and Hardware in the Loop Simulation (HILS). For the present verification, the simulation method used is HILS.

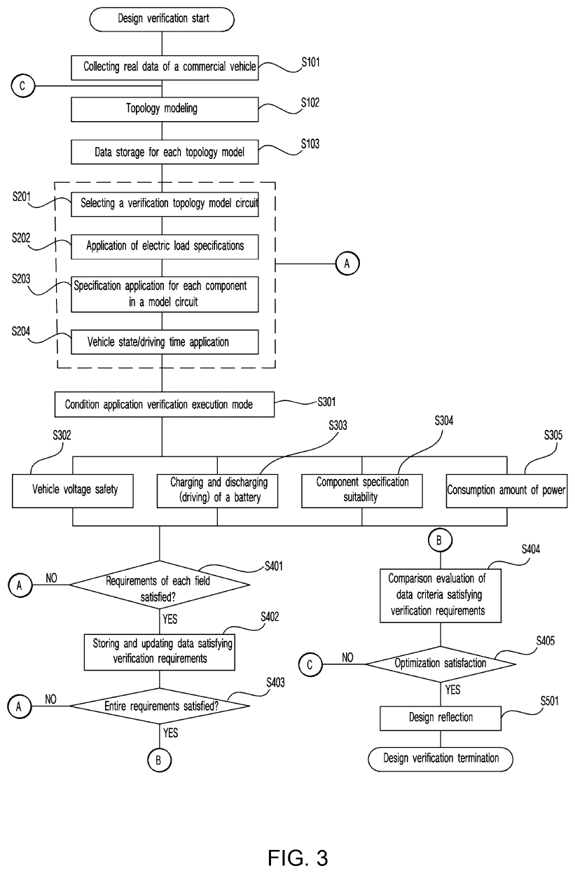

FIG. 3 is an exemplary flow diagram illustrating a design verification process for a low-voltage battery unit of an FCEV type commercial special purpose vehicle according to the present disclosure, which will be described in detail below.

First, in the process of step S101, vehicle actual data for modeling the topology of the commercial vehicle low-voltage battery unit are collected. Here, the collected data are real data such as consumption measurement amount of each electric load using the DC12V or DC24V of the vehicle as a driving power, dual power low-voltage circuit configuration, LDC/BEQ electrical specification, control logic, wire resistance information, and vehicle information.

Thereafter, in step S102, the entire circuit and unit components (battery, LDC, BEQ, etc.) configuring the low-voltage battery unit are modeled, and the voltage data and the current data for the real object are used to be reflected in the configuration model.

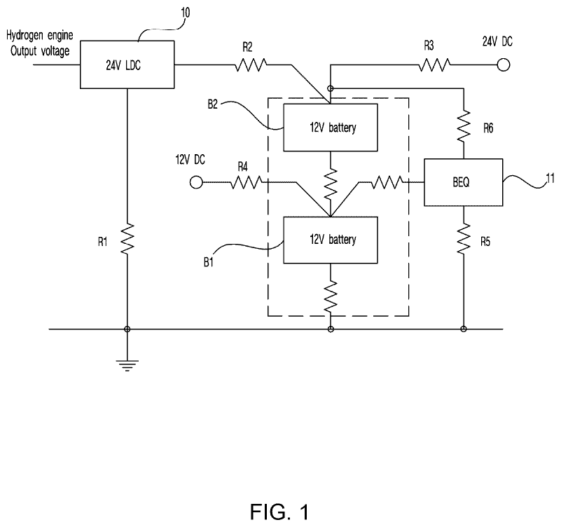

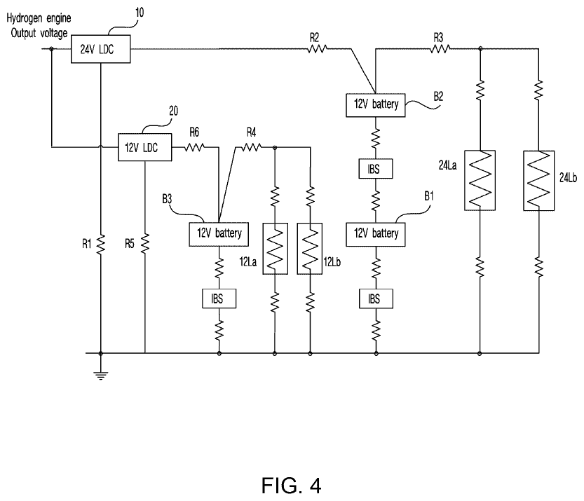

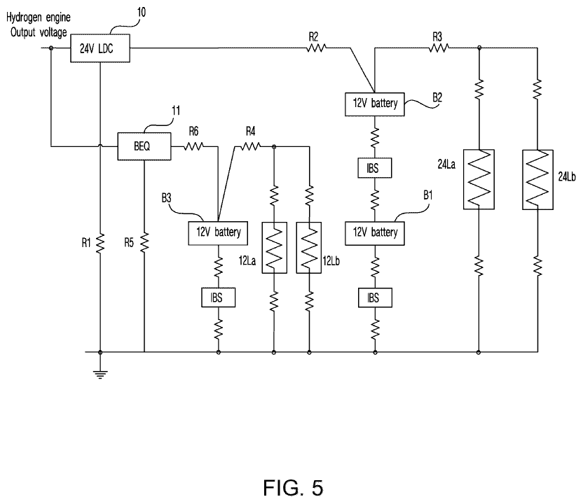

That is, a model of a configuration before the improvement of the low-voltage battery unit to be verified (the configuration according to FIG. 1 is referred to as “topology 1”), a configuration to be changed according to the improvement purpose (the configuration according to FIGS. 2 and 4 is referred to as “topology 2”), and a modified configuration of a configuration to be changed (a configuration battery according to FIG. 5 is referred to as “topology 3”) is constructed.

In this case, FIG. 4 is an exemplary diagram in which the configuration shown in FIG. 2 is configured as a simulation circuit model in order to verify a design change of a low-voltage battery unit of an FCEV type commercial special purpose vehicle according to the present disclosure, and FIG. 5 is an exemplary diagram in which a modified simulation circuit model is configured in order to compare and verify the design change shown in FIG. 4.

In FIGS. 4 and 5, reference numerals 12La and 12 Lb denote electric field loads for the DC12V, and reference numerals 24La and 24 Lb denote electric field loads for the DC24V.

Also, an intelligent battery sensor (IBS) is a component for measuring charge/discharge voltage states of the low-voltage batteries B1, B2, and B3. Resistance elements without reference numerals are resistors for stabilizing power supplied to a load side of a rear end or internal resistance of the battery, and their description will be omitted.

When a topology modeling is performed in step S102, it is stored through the process of step S103. In this case, it should be noted in advance that the process of step S103 may interwork with the process of step S102.

Through the above-described steps S101 to S103, a simulation environment for verification according to the design change is constructed.

Thereafter, the verification condition is set through the processes of steps S201 to S204, and in step S201, any one of the circuits of the topology modeled in step S102 is selected. Typically, the prepared topology is selected according to the order of preparation.

Thereafter, in step S202, the specifications of the electric load for the DC12V or the DC24V driving power supply included in the FCEV type commercial special purpose vehicle are applied, and in step S203, the specifications of the components, for example, the IDS, the BEQ, and the battery are applied to the circuit of the topology selected in step S201.

When the setting of the circuit components of the topology to be verified and the electric field load is completed through the above-described steps S201 to S203, simulation data for the driving state is set in step S204 in order to check the operation state while the actual vehicle is running.

When the preparation for the verification simulation is completed through the above-described process, the verification simulation is performed through the processes of steps S301 to S305, and the processes of steps S301 to S305 are simplified for ease of description and are not limited thereto.

In step S301, various environments that may occur in actual driving are created with respect to the simulation environment set through steps S201 to S204 to inspect performance, change, and safety of each component, and since the respective inspections are not sequentially performed but are simultaneously performed in combination, a data processing function for parallel progress is performed.

In step S302, it is determined whether the stable power is supplied to the electric load of the vehicle based on the topology selected in step S201, and in step S303, the charging/discharging efficiency of the battery is checked based on the topology selected in step S201. Further, in step S304, the suitability of the specifications of the component selected in step S203 is checked, and in step S305, the total consumption amount of power is checked.

Therefore, the processes of steps S301 to S305 can simulate situations of various conditions using the verification environment constructed through the processes of step S201 through step S204.

Thereafter, in the process of step S401, it is determined whether the results reviewed in the process of steps S302 to S305 satisfy the predetermined requirements (the normal stability reference value) for each checking field, and when they are not satisfied, the process proceeds to any one of steps S201 to S204 in order to apply another topology feature, or change the specifications of the components (electrical specifications, control logic), the vehicle conditions (vehicle state {parking/ACC/driving}, driving time), and the conditions of the 12/24V consumption load.

That is, in order to change an item evaluated as unsatisfactory, the process proceeds to the setting mode of the corresponding item to change the existing setting value to another setting value. It should be noted that the explanation of the processes in steps S301 to S305 is simplified for ease of description, but this simplification does not obscure or affect the operation of the actual verification system. Thereafter, if it is determined in step S401 that the preset requirements for each checking field are satisfied, data for each checking field (target) satisfying the requirements is stored through step S402, and if the checking target is changed, the data is updated accordingly.

That is, for example, if it is assumed that the low-voltage battery is checked by performing the component specification suitability determination in step S304, the low-voltage battery specification may be largely divided into the CMF battery or the AGM battery, and when both the CMF battery and the AGM battery pass through the preset reference value, each corresponding data are individually stored in step S402.

Thereafter, in step S403, it is determined whether the results reviewed in steps S302 to S305 have passed all the preset requirements for each inspection field. That is, if it is determined that all the topologies modeled in step S102 have passed the predetermined requirements for each inspection field through the processes of steps S302 to S305, the process proceeds to step S404, the data satisfying the verification requirements are arranged for all the topologies modeled in step S102, and the arranged data are compared and evaluated.

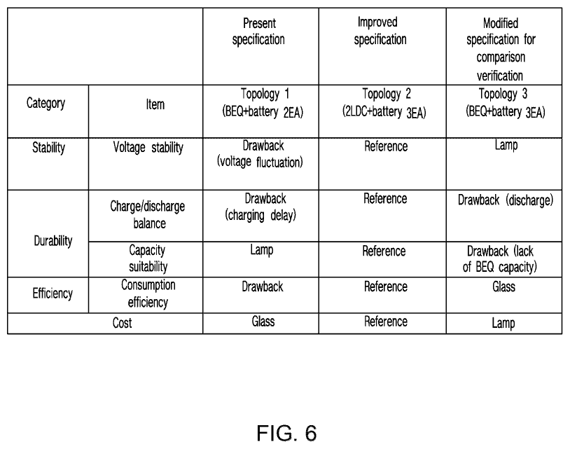

The result of the comparison and evaluation in step S404 is summarized as shown in FIG. 6.

Therefore, as a result of the verification, it was confirmed that the topology 2 according to the present disclosure is advantageous in terms of voltage stability, charge/discharge balance, and capacity suitability compared to the topology 1 (the current configuration) and the topology 3 (the modified configuration for comparison and verification). This indicates the need to improve the feature of the current low-voltage battery unit. Furthermore, it is reasonable to separate the low-voltage battery into the DC12V and the DC24V, based on the analysis of voltage stability, charge/discharge balance, and total consumption amount of the vehicle load.

However, the rise in cost is a drawback. Despite this, it has the advantage of solving the problems of increased consumer dissatisfaction and decreased product reliability.

Therefore, as a result of adjusting and determining the specifications of each component through the verification simulation according to the present disclosure in a more detailed manner, it was confirmed that the low-voltage battery unit shown in FIG. 2 is optimal.

In FIG. 2, it has been verified that a battery dedicated to DC24V referred to by reference numerals B1 and B2 is replaced with a model of an Absorbent Glass Mat (AGM) 220 Ah specification from the existing CMF 230 Ah model, and a battery dedicated to DC12V referred to by reference numeral B3 is used with a model of the AGM 50 Ah specification to provide optimal and reliable performance while reducing a cost increase rate.

Therefore, the verified improvement matters are reflected in the final design through the process of step S501. Therefore, it is possible to minimize the evaluation cost and development period by modifying the vehicle design specifications based on the results of the verification simulation or reflecting them in the actual vehicle evaluation.

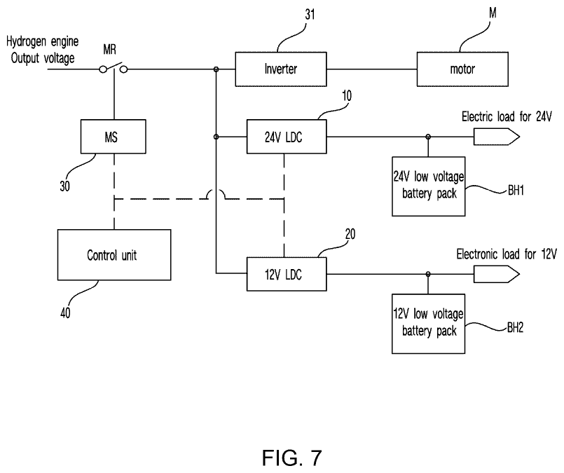

FIG. 7 is an exemplary diagram of a power system configuration of an FCEV type commercial special purpose vehicle to which a low-voltage battery unit of which the design is changed is applied according to the present disclosure, and includes a motor M, an inverter 31 for driving the motor M, a hydrogen fuel cell (not shown) for outputting high-voltage power as a power source for operating the motor M, a main relay MR. for opening and closing a power connection path between the hydrogen fuel cell and the inverter 31 according to a control signal, an Management System (MS) 30 for controlling on/off of the main relay MR. by generating the control signal, an 24V LDC 10 for converting the high-voltage power into DC 24V and outputting the DC 24V, a 24V battery pack BH1 (first low-voltage battery) charged by the power output from the 24V LDC 10 and supplying power to an electric load for 24V using the DC 24V, a low 12VLDC 20 for converting the high-voltage power into DC 12V and outputting the DC 12V, a 12V battery pack BH2 (second low-voltage battery) charged by power output from the 12V LDC 20 and supplying power to an electric load for 12V using the DC 12V, and a control unit 40 for controlling the operation states of the 24V LDC 10 and the 12V LDC 20.

In the power system of the FCEV special purpose vehicle according to the present disclosure configured as described above, the 24V low-voltage battery pack BH1 is configured of two AGM batteries connected in series while having the 12V-105 Ah specification, and the 12V low-voltage battery pack BH2 is configured of one AGM battery having the 12V-50 Ah specification.

Therefore, in the case of an FCEV type commercial special purpose vehicle, the 12V low-voltage battery pack BH2 supplies power to the 12V electric load and the 24V low-voltage battery pack BH1 supplies power to the 24V electric load. This configuration allows the commercial HVDC special purpose vehicle to be independently driven by each of the battery packs BH1 and BH2.

Therefore, the deviation of the charge and discharge flow between the battery packs BH1 and BH2 does not occur, and the aging or complete discharge of one side does not affect the other side, such that the maintenance is easy and the occurrence of the consumer's complaints can be reduced.

Although the preferred embodiments of the present disclosure have been illustrated and described above, the present disclosure is not limited to the above-described specific embodiments, and various modifications may be made by those skilled in the art without departing from the spirit of the present disclosure claimed in the claims, and such modifications should not be individually understood from the technical spirit or the view of the present disclosure.

What is claimed is:

1. A low-voltage battery unit for a vehicle, comprising:
a first low-voltage DC-DC converter (LDC) that converts a high-voltage power into a first low-voltage and outputs the first low-voltage;
a first low-voltage battery charged by a power output from the first LDC and supplying a power of the first low-voltage to a first electric load;
a second LDC that converts the high-voltage power into a second low-voltage and outputs the second low-voltage; and
a second low-voltage battery charged by a power output from the second LDC and supplying a power of the second low-voltage to a second electric load.

2. The low-voltage battery unit of claim 1, wherein the high-voltage power is supplied from a hydrogen fuel cell.

3. The low-voltage battery unit of claim 1, wherein the first low-voltage battery comprises two 12V-105 Ah absorbed glass mat (AGM) batteries connected in series.

4. The low-voltage battery unit of claim 1, wherein the second low-voltage battery comprises one 12V-50 Ah AGM battery.

5. The low-voltage battery unit of claim 1, wherein the first LDC comprises 24V LDC.

6. The low-voltage battery unit of claim 1, wherein the second LDC comprises 12V LDC.

7. A design verification method for verifying a structural change of a low-voltage battery unit for supplying DC24V and DC12V to electric loads in a vehicle, the method comprising:
collecting vehicle actual data;
modeling respective topology circuits of a first topology of a current structure, a second topology of an improvement structure to be verified, and a third topology obtained by modifying the second topology, based on the vehicle actual data;
constructing electric models of components applicable to each of the modeled topology circuits, the specification of the electric loads, and an operating environment of the vehicle, in a simulation environment; and
verifying by simulation, obtaining results of electric characteristics through a change of a verification condition in the simulation environment, and comparing the results for the first topology to the third topology to verify an optimized structure and corresponding components of the structure.

8. The method of claim 7, wherein the step of verifying by simulation comprises:
selecting a verification topology model circuit from the stored topology models.

9. The method of claim 8, wherein the step of verifying by simulation further comprises:
applying electric load specifications to the selected verification topology model circuit.

10. The method of claim 8, wherein the step of verifying by simulation further comprises:
applying specifications for each component in the model circuit of the selected verification topology model circuit.

11. The method of claim 8, wherein the step of verifying by simulation further comprises:
applying vehicle state and driving time conditions to the selected verification topology model circuit.

12. The method of claim 7, further comprising:
executing condition application verification mode by assessing vehicle voltage safety, charging and discharging of a battery, component specification suitability, or consumption amount of power to ensure that requirements of each field are satisfied.

13. The method of claim 7, wherein the vehicle actual data comprise a consumption measurement amount of each electric load of the vehicle, a configuration of a dual power low-voltage circuit, a battery specification, an LDC/BEQ (battery equalizer) electrical specification, control logic, wire resistance information, or vehicle information.

14. A power system for a vehicle, comprising:
an inverter for driving a motor;
a high-voltage power source for outputting a high-voltage power as a power source for operating the motor;
a main relay for opening or closing a power connection path between the high-voltage power source and the inverter according to a control signal;
a management system (MS) for controlling on/off of the main relay by generating the control signal;
a first low-voltage DC-DC converter (LDC) for converting the high-voltage power into a first low-voltage and outputting the first low-voltage;
a first low-voltage battery charged by a power output from the first LDC and supplying a power of the first low-voltage to a first electric load;
a second LDC for converting the high-voltage power into a second low-voltage and outputting the second low-voltage; and
a second low-voltage battery charged by the power output from the 2LDC and supplying a power of the second low-voltage to a second electric load.

15. The power system of claim 14, further comprising: a control unit configured to control operation states of the MS, the first LDC, and the second LDC.

16. The power system of claim 14, wherein the high-voltage power source comprises a hydrogen fuel cell.

17. The power system of claim 14, wherein the first low-voltage battery comprises two 12V-105 Ah AGM batteries connected in series.

18. The power system of claim 14, wherein the second low-voltage battery comprises one 12V-50 Ah AGM battery.

19. The power system of claim 14, wherein the first LDC comprises 24V LDC.

20. The power system of claim 14, wherein the second LDC comprises 12V LDC.
